(19) United States
(12) Patent Application Publication
(10) Pub. No.: US 2006/0075968 A1
(43) Pub. Date: Apr. 13, 2006

(54) Leak detector and process gas monitor

(75) Inventors: Samuel Leung, San Jose, CA (US); Ulrich A. Bonne, Sunnyvale, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/087,193

(22) Filed: Mar. 23, 2005

Related U.S. Application Data
(60) Provisional application No. 60/617,714, filed on Oct. 12, 2004.

(51) Int. Cl. C23C 16/00; C23F 1/00; H01L 21/306; B01J 19/08

(52) U.S. Cl. 118/723 R; 118/715; 156/345.28; 427/457; 427/248.1

(57) ABSTRACT

A method and apparatus for a plasma enhanced chemical vapor deposition system for processing one or more flat panel display substrates comprising a vacuum deposition process chamber configured to contain gas, a residual gas analyzer configured to analyze the gas within the process chamber and to provide feedback, and a controller to monitor feedback from the gas analyzer. Also, a method for identifying a process upset within a plasma enhanced chemical vapor deposition system configured to process flat panel display substrates comprising determining a historical slope of a line for partial pressure as a function of time, calculating a new slope of a line based on partial pressure measurements by a residual gas analyzer, comparing the historical and new slopes, and sending a signal to an operator.

### CROSS-REFERENCE TO RELATED APPLICATIONS

This application claims benefit of U.S. provisional patent application Ser. No. 60/617,714, filed Oct. 12, 2004, which is herein incorporated by reference.

### BACKGROUND OF THE INVENTION

1. Field of the Invention

Embodiments of the present invention generally relate to flat panel display and semiconductor wafer processing and methods, and more particularly, to methods and systems for monitoring the status of flat panel display processing systems.

2. Description of the Related Art

Chemical vapor deposition (CVD) is widely used in the semiconductor industry to deposit films such as intrinsic and doped amorphous silicon (a-Si), silicon oxide (SiₓO_{y}), silicon nitride (SiᵣNₛ), and silicon oxynitride, on a substrate. Modern semiconductor CVD processing is generally done in a vacuum chamber by using precursor gases which dissociate and react to form the desired film. In order to deposit films at low temperatures and relatively high deposition rates, plasma can be formed from the precursor gases in the chamber during the deposition. Such processes are known as plasma enhanced CVD processes or PECVD. Other systems such as HDP-CVD may also be desirable.

State of the art CVD semiconductor processing chambers are made of aluminum and include a support for the substrate and a port for entry of the required precursor gases. When plasma is used, the gas inlet and/or the substrate support is connected to a source of power, such as a radio frequency (RF) power source. A vacuum pump is also connected to the chamber to control the pressure in the chamber and to remove the various gases and contaminants generated during the deposition.

In all semiconductor processing, contaminants in the chamber must be kept to a minimum. During the deposition process, the film is deposited not only on the substrate, but also on walls, shields, the substrate support, and other surfaces, in the chamber. During subsequent depositions, the film on the chamber surfaces can crack or peel, causing contaminants to fall on the substrate. This causes problems and damage to particular devices on the substrate.

Thus, the CVD chamber must be periodically cleaned. As part of, or separate from, the cleaning regime, the chamber is also tested for gas leaks. Currently, to test for leaks, the chamber gases are evacuated, an isolation valve separating the chamber from the vacuum pumps is closed, and the pressure increase (if any) in the chamber is measured. If there are leaks, the pressure will increase, whereas without a vacuum leak, the pressure will remain constant. This rate-of-rise testing may take up to 10 minutes to perform. Over 24 hours, that can add up to 2 to 3 hours of pressure drop testing for one chamber, depending on frequency of testing.

If the pressure rise is not within an expected range, the chamber may be experiencing a leak. The leak may be from a faulty seal in a process gas valve. Alternatively, it may be a leak across any of the O-rings used to seal the chamber from the atmosphere, e.g. view ports, chamber lid, feedthrough ports, etc., within the system that is introducing atmospheric oxygen, nitrogen, and argon into the processing chamber. Finally, the abnormal pressure increase may be a function of cleaning solvent such as water or isopropyl alcohol evaporating or outgassing (desorbing) from the chamber walls in the system. When the pressure rise is the only indicator of pressure abnormalities in the system, it is difficult to determine which of these conditions may be the cause of the unexpected pressure increase.

Currently, the frequency and duration of a cleaning cycle are typically determined by trial and error or empirically collected historical data. For instance, a chamber may be scheduled for cleaning after processing a predetermined number of substrates, regardless of the condition of the chamber. With respect to duration, an extra 20 to 30 percent of clean time is typically added to the cleaning cycle, without regard to considering the damage that the extra clean time may cause to the chamber and the components contained therein.

Therefore, a need exists in the art for an improved method and system for detecting system leaks; distinguishing between atmospheric leaks, internal process gas leaks, and solvent evaporation chamber partial pressure changes; and for consistently monitoring and recording chamber conditions to predict efficient future production and cleaning of a PECVD system configured to process flat panel display substrates.

### SUMMARY OF THE INVENTION

The present invention generally provides a method and apparatus for a plasma enhanced chemical vapor deposition system for processing one or more flat panel display substrates comprising a vacuum deposition process chamber configured to contain gas, a residual gas analyzer configured to analyze the gas within the process chamber and to provide feedback, and a controller to monitor feedback from the gas analyzer. Also, the present invention generally provides a method for identifying a process upset within a plasma enhanced chemical vapor deposition system configured to process flat panel display substrates comprising determining a historical slope of a line for partial pressure as a function of time, calculating a new slope of a line based on partial pressure measurements by a residual gas analyzer, comparing the historical and new slopes, and sending a signal to an operator.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a sectional view of an embodiment of a plasma enhanced chemical vapor deposition system.

FIG. 2 is a chart illustrating observed partial pressure measurements of two gases as a function of time of a plasma enhanced chemical vapor deposition system.

### DETAILED DESCRIPTION

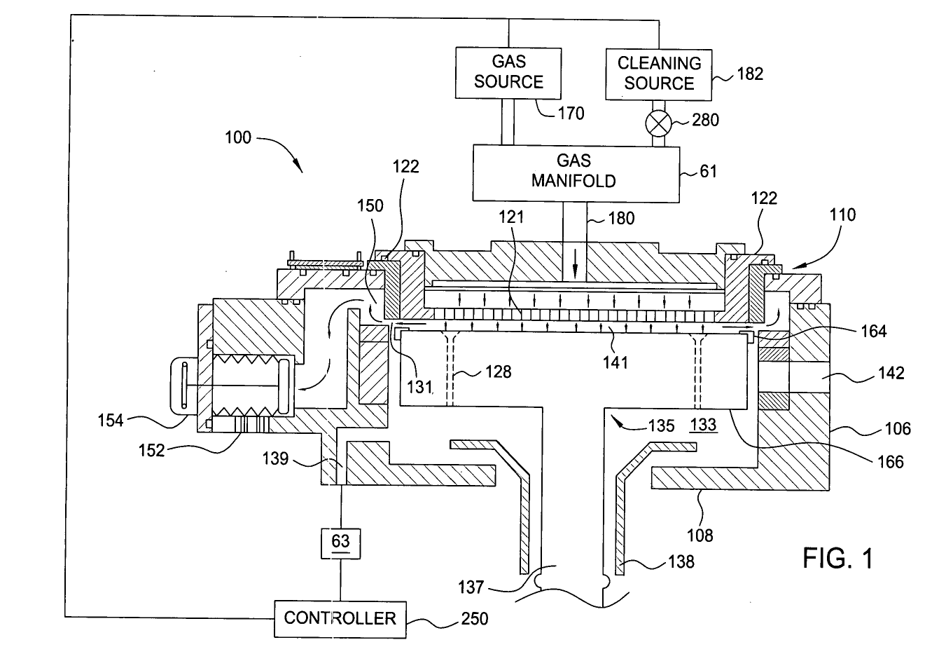

FIG. 1 illustrates a schematic cross-sectional view of one embodiment of a plasma enhanced chemical vapor deposition (PECVD) system 100, which is available from AKT, a division of Applied Materials, Inc., of Santa Clara, Calif. The system 100 includes a vacuum deposition process chamber 133. The process chamber 133 has walls 106 and a bottom 108 that partially define a processing region 141. The walls 106 and the bottom 108 are typically fabricated from a unitary block of aluminum or other material compatible with processing. The walls 106 have an opening 142 for transferring flat panel display substrates into and out of the process chamber 133. Examples of flat panel display substrates include glass substrates, polymer substrates, and the like. Although various embodiments of the invention are described with reference to PECVD systems, other embodiments of the invention may apply to cluster process systems, in-line systems, stand-alone systems and the like.

A temperature controlled substrate support assembly 135 is centrally disposed within the processing chamber 133. The support assembly 135 is configured to support a flat panel display substrate during processing. The substrate support assembly 135 may have an aluminum body that encapsulates at least one embedded heater (not shown). The heater, such as a resistive element, is coupled to an optional power source and controllably heats the support assembly 135 and the flat panel display substrate positioned thereon to a predetermined temperature. Typically, in a CVD process, the heater maintains the flat panel display substrate at a uniform temperature between about 150 to about 460 degrees Celsius, depending on the deposition processing parameters for the material being deposited.

Generally, the support assembly 135 has a lower side 166 and an upper side 164. The upper side 164 is configured to support the flat panel display substrate. The lower side 166 has a stem 137 coupled thereto. The stem 137 couples the support assembly 135 to a lift system (not shown) that moves the support assembly 135 between an elevated processing position and a lowered position that facilitates substrate transfer to and from the processing chamber 133. The stem 137 additionally provides a conduit for electrical and thermocouple leads between the support assembly 135 and other components of the system 100.

The bottom 108 of the processing chamber 133 is configured to house a gas conduit 139 to a residual gas analyzer 63. The residual gas analyzer may be any type of mass spectrometer, but preferably is a quadrupole mass spectrometer. Alternatively, the mass spectrometer may be a high resolution mass spectrometer. The residual gas analyzer 63 is configured to measure the partial pressure and composition of each individual gas in the system. Several commercial suppliers such as Stanford Research Systems may provide quadrupole mass spectrometers. The residual gas analyzer 63 is in communication with a controller 250. The controller 250 also may be in communication with the process and purge gas feed lines, the exhaust valve, and other components to control the gas distribution, inlet, and exhaust of the chamber.

A bellows (not shown) may be coupled between the stem 137 and sleeve 138 which surrounds it. The bellows provides a vacuum seal between the processing region 141 and processing chamber 133. Although the substrate is not in processing chamber 133, it is still under vacuum, at the same pressure as the region 141. Thus, the residual gas analyzer 63 can sample the process chamber conditions through the sample port, while allowing vertical movement of the support assembly 135.

The support assembly 135 may additionally support a circumscribing shadow frame (not shown). Generally, the shadow frame is configured to prevent deposition at the edge of the flat panel display substrate and the support assembly 135 so that the substrate does not stick to the support assembly 135. The support assembly 135 has a plurality of holes 128 disposed therethrough that are configured to accept a plurality of lift pins (not shown). The lift pins are typically comprised of ceramic or anodized aluminum. The lift pins may be actuated relative to the support assembly 135 by an optional lift plate (not shown) to project from the support surface (not shown), thereby placing the substrate in a spaced-apart relation to the support assembly 135.

The processing chamber 133 further includes a lid assembly 110, which provides an upper boundary to the processing region 141. The lid assembly 110 typically can be removed or opened to service the processing chamber 133. The lid assembly 110 may be fabricated from aluminum (Al). The lid assembly 110 includes an exhaust plenum 150, which is configured to channel gases and processing by-products uniformly from the processing region 141 and out of the processing chamber 133.

The lid assembly 110 typically includes an entry port 180 through which process and clean gases are introduced into the processing chamber 133 through a gas manifold 61. The gas manifold 61 is coupled to a process gas source 170 and a clean gas source 182. The clean gas source 182 typically provides a cleaning agent, such as fluorine radicals, that is introduced into the processing chamber 133 to remove deposition by-products and films from processing chamber hardware. NF₃ may be used as the clean gas to provide the fluorine radicals. Other clean gases such as N₂, O₂ and Ar may be combined with NF₃ to provide the fluorine radicals. The clean gas source 182 may incorporate a remote plasma clean source configured to generate etchant plasma. Such remote plasma clean source is typically remote from the processing chamber 133 and may be a high density plasma source, such as a microwave plasma system, toroidal plasma generator or similar device.

In one embodiment, a valve 280 may be disposed between the clean source 182 and the gas manifold 61. The valve 280 is configured to selectively allow or prevent clean gases from entering the gas manifold 61. During cleaning, the valve 280 is configured to allow the clean gases from the clean gas source 182 to pass into gas manifold 61, where they are directed through the entry port 180 into the processing region 141 to etch the inner chamber walls and other components contained therein. During deposition, the valve 280 is configured to prevent clean gases from passing into the gas manifold 61. In this manner, the valve 280 isolates the clean processes from the deposition processes.

The processing chamber 133 further includes a gas distribution plate assembly 122 coupled to an interior side of the lid assembly 210. The gas distribution plate assembly 122 includes a perforated area 121 through which process and clean gases are delivered to the processing region 141. The perforated area 121 of the gas distribution plate assembly 122 is configured to substantially have a similar area, size, and shape of the flat panel display substrate and to provide uniform distribution of gases passing through the gas distribution plate assembly 122 into the processing chamber 133.

In operation, deposition process gases flow into the processing chamber 133 through a gas manifold 61 and the entry port 180. The gases then flow through the perforated area 121 of the gas distribution plate assembly 122 into the processing region 141. An RF power supply (not shown) may be used to apply electrical power between the gas distribution plate assembly 122 and the support assembly 135 to excite the process gas mixture to form plasma. The constituents of the plasma react to deposit a desired film on the surface of the substrate on the support assembly 135. The RF power is generally selected commensurate with the size of the substrate to drive the chemical vapor deposition process.

The deposition process gases may be exhausted from the process chamber 133 through a slot-shaped orifice 131 surrounding the processing region 141 into the exhaust plenum 150. From the exhaust plenum 150, the gases flow through a vacuum shut-off valve 154 into an exhaust outlet 152 which comprises a discharge conduit 60 that connects to an external vacuum pump (not shown).

The residual gas analyzer 63 may be configured to measure for an unlimited number of gases, however the software that provides feedback to the controller may be limited to 10 gases at a time. The residual gas analyzer measures both the composition of gas and the partial pressure of each gas component in the system. Thus, the controller can monitor simultaneously the identity and concentration of the gas components in the system. The controller can track changes in the overall chamber pressure, the individual gas components, and the gas composition, thus indicating a process upset or other process change. Over time, the slope of the line formed by plotting the partial pressure of a gas as a function of time can be recorded. This historical data may be used to improve process performance by tracking trends, predicting desirable cleaning or deposition gas inlet parameters, or by providing other analytical support.

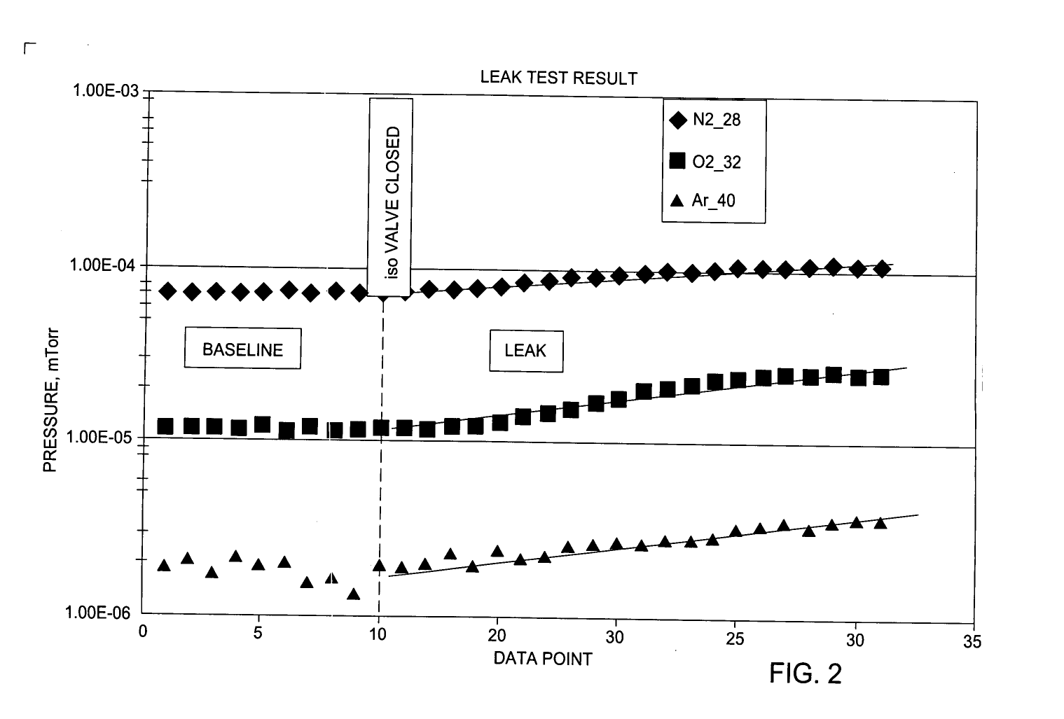

FIG. 2 is a chart illustrating observed partial pressure measurements of oxygen and nitrogen as a function of time of a plasma enhanced chemical vapor deposition system. As continuous concentration information is collected by the residual gas analyzer, the controller can notice changes in the slope of the partial pressure as a function of time. If, when the processing region 141 and exhaust region 150 are isolated from the vacuum pumps by isolation valve 154, the measured partial pressures of oxygen and nitrogen increase simultaneously, the controller may alert the operator that there is an atmospheric leak in the system. The portion to the left of the dashed vertical line in FIG. 2 shows the pressure of N₂ and O₂ while the isolation valve 154 is open. Closing isolation valve 154 at the time indicated by the dashed vertical line results in an increase in pressure of N₂ and O₂ due to the presence of an atmospheric leak into the chamber. This is the portion of the graph to the right of the dashed vertical line in FIG. 2. Argon may also be tracked with oxygen and nitrogen, and the partial pressure as a function of time would show a slope comparable to that of N₂ and O₂. However, due to the lower concentration of Ar in atmospheric air, the measured pressure of Ar would be lower than that of N₂ and O₂. In the example presented by FIG. 2, the operator was alerted in less than 10 seconds that the system had an atmospheric leak, while it would have taken at least 6 to 10 minutes in a conventional rate-of-rise test that tracked only system pressure rises in the system. The controller may continuously track the partial pressure measurements and calculate the slopes of partial pressures. Traditional statistical analysis tools and calculations may be used.

The advantages of using the continuous, real time residual gas analyzer are numerous. Generally, process excursion will be detected more quickly than in those systems that monitor the system pressure drop. Atmospheric leaks may be detected more quickly with the residual gas analyzer. The individual chemical partial pressure feedback from the analyzer may be used to determine if process gases are leaking into the system and thus causing a pressure rise. Historical tracking of the feedback from the analyzer may be used to develop new process regimes or to predict future cleaning cycles. The feedback from the analyzer may also be used to track changes in the partial pressure of solvents used to clean the chamber such as water or isopropyl alcohol, thus preventing the operator from mistakenly believing there is an atmospheric leak when there is merely a cleaning solvent evaporating or desorbing in the system.

Finally, the analyzer is desirable for cycle-purge, a cyclical cleaning process that cyclically introduces inert gases into the chamber, evacuates all gas from the chamber, and introduces additional inert gas into the chamber to reduce particles and water or other solvent content along the chamber surfaces. The analyzer is desirable because it can test for solvent matter continuously. Thus, the cycle-purge effectiveness as a cleaning regime is established when the concentration of solvent or particulate matter is static.

While the foregoing is directed to embodiments of the present invention, other and further embodiments of the invention may be devised without departing from the basic scope thereof, and the scope thereof is determined by the claims that follow.

1. A plasma enhanced chemical vapor deposition system for processing one or more flat panel display substrates, comprising:
a vacuum deposition process chamber configured to contain gas;
a residual gas analyzer configured to analyze the gas within the process chamber and to provide feedback; and
a controller to monitor feedback from the gas analyzer.

2. The system of claim 1, wherein the controller controls the flow of gases into the chamber.

3. The system of claim 1, wherein the controller controls the exhaust of gases out of the chamber.

4. The system of claim 1, wherein the gas analyzer is a mass spectrometer.

5. The system of claim 4, wherein the mass spectrometer is a quadrupole mass spectrometer.

6. The system of claim 3, wherein the controller records process data.

7. The system of claim 1, wherein the residual gas monitor analyzes at least two gases.

8. The system of claim 7, wherein the at least two gases are nitrogen and oxygen.

9. A method for identifying a process upset within a plasma enhanced chemical vapor deposition system configured to process flat panel display substrates, comprising:
determining a historical slope of a line for partial pressure as a function of time;
calculating a new slope of a line based on partial pressure measurements by a residual gas analyzer;
comparing the historical and new slopes; and
sending a signal to an operator.

10. The method of claim 9, wherein the signal to an operator is selected to notify the operator there is a process upset or there is not a process upset.

11. The method of claim 9, wherein the historical slope is determined by:
monitoring a plurality of partial pressure measurements; and
performing traditional statistical analysis to determine a mean and a deviation.

12. The method of claim 9, wherein at least two gases are monitored and analyzed.

13. The method of claim 12, wherein the historical and new slopes of the partial pressure measurements as a function of time of the at least two gases are recorded.

14. The method of claim 13, wherein changes in the slopes of at least two gases are compared to each other.

15. The method of claim 14, wherein the operator is notified when the at least two gases have similar changes in the new slopes compared to the historical slopes.

16. The method of claim 13, wherein the at least two gases are oxygen and nitrogen.

17. The method of claim 16, wherein the at least two gases further comprises argon.

18. The method of claim 9, wherein the gas analyzer is a mass spectrometer.

19. The method of claim 18, wherein the mass spectrometer is a quadrupole mass spectrometer.

20. The method of claim 9, further comprising sending a signal to a controller.
